(19) United States
(12) Patent Application Publication
(10) Pub. No.: US 2009/0175707 A1
(43) Pub. Date: Jul. 9, 2009

(54) Controlled deflection of large area semiconductor substrates for shipping and manufacturing containers

(76) Inventor: Anthony C. Bonora, Fremont, CA (US)

Correspondence Address: MARTINE PENILLA & GENCARELLA, LLP, 710 LAKEWAY DRIVE, SUITE 200, SUNNYVALE, CA, 94085, US

(21) Appl. No.: 12/348,276

(22) Filed: Jan. 3, 2009

Related U.S. Application Data
(60) Provisional application No. 61/018,782, filed on Jan. 3, 2008.

(51) Int. Cl. H01L 21/67

(52) U.S. Cl. 414/222.01; 211/41.18; 414/806

(57) ABSTRACT

A substrate container for storing at least one substrate is provided. The substrate container includes a housing assembly encompassing the at least one substrate, the housing assembly having a container door for access into an inner region of the housing assembly. The housing assembly includes a support structure defined along sidewalls of the housing assembly. The support structure has a plurality of edge support constraints protruding into the inner region of the housing assembly. The plurality of edge support constraints support opposing edge regions of the at least one substrate so as to cause the at least one substrate to deflect around an axis.

### CLAIM OF PRIORITY

The present application claims priority under 35 U.S.C. §119(e) from U.S. Provisional Patent Application No. 61/018,782, filed Jan. 3, 2008 which is incorporated by reference in its entirety for all purposes.

### BACKGROUND

Large area substrates for semiconductor device production are typically 300 mm or larger in diameter. To conserve material, the substrate thickness is typically less than one millimeter and the substrate/wafer has bending characteristics similar to a thin membrane. Minimizing the magnitude of bending and deflection from a flat plane is desirable for general wafer handling in a manufacturing environment. However, in shipment the substrate is subject to shock and vibration conditions that may cause deflection and resonance conditions that would result in damage or breakage. As a transition is made to 450 mm diameter substrates in the manufacturing of integrated circuits the challenges for handling the substrates continue to mount.

It is within this context that the embodiments arise.

### SUMMARY

Broadly speaking, the present invention fills these needs by providing a substrate container providing support for large area substrates. It should be appreciated that the present invention can be implemented in numerous ways, including as a method, a system, or an apparatus. Several inventive embodiments of the present invention are described below.

In one embodiment, a substrate container for storing at least one substrate is provided. The substrate container includes a housing assembly encompassing the at least one substrate, the housing assembly having a container door for access into an inner region of the housing assembly. The housing assembly includes a support structure defined along sidewalls of the housing assembly. The support structure has a plurality of edge support constraints protruding into the inner region of the housing assembly. The plurality of edge support constraints support opposing edge regions of the at least one substrate so as to cause the at least one substrate to deflect around an axis.

In another embodiment, a method for supporting a semiconductor substrate within a container is provided. The method includes delivering the semiconductor substrate to the container and closing a door to the container to cause the semiconductor substrate to bend around an axis. Closing the door includes latching the door for transportation of the container.

Other aspects and advantages of the invention will become apparent from the following detailed description, taken in conjunction with the accompanying drawings, illustrating by way of example the principles of the invention.

### BRIEF DESCRIPTION OF THE DRAWINGS

Aspects of the present invention will become apparent from the following detailed description, taken in conjunction with the accompanying drawings, illustrating by way of example the principles of the invention.

FIG. 1 is a simplified schematic diagram illustrating a maximum spread end effector in accordance with one embodiment of the invention.

FIG. 2 is a simplified schematic diagram illustrating a configuration for a FOUP in accordance with one embodiment of the invention.

FIG. 3 is a simplified schematic diagram illustrating a perspective view of an FOUP in accordance of one embodiment of the invention.

FIGS. 4A and 4C illustrate various container support mechanisms for use when shipping substrates and transporting substrates in accordance with one embodiment of the invention.

### DETAILED DESCRIPTION

An invention is described for a system and container for handling semiconductor substrates involved in semiconductor manufacturing operations. It will be obvious, however, to one skilled in the art, that the present invention may be practiced without some or all of these specific details. In other instances, well known process operations have not been described in detail in order not to unnecessarily obscure the present invention.

The embodiments described herein include a semiconductor substrate container for storing semiconductor substrates so as to minimize exposure to harmful effects from vibration and resonance experienced by the substrates during transport. The embodiments described herein provide support for a semiconductor substrate by purposefully deflecting the substrate to provide for greater rigidity and protection against vibration and resonance forces experienced during transport of the substrate in a container. It should be appreciated that the transition to a larger diameter wafer, i.e., the transition from 300 mm wafers to 450 mm wafers, may not be accompanied by a corresponding increase in thickness of the wafer, therefore, the embodiments described herein support the substrate in a manner that accounts for the increased stresses placed on the substrate. Consequently, the embodiments prevent possible damage to the semiconductor circuitry disposed on the surface of the substrate due to any increased stresses.

As will be explained in more detail below, in one embodiment, the support points contacting the surface of the substrate being supported force deflection of the wafer along one or more bend axes. It should be noted that while the embodiments described illustrate designs of a container and end effector together, this is not meant to be limiting. That is, the embodiments of the container described herein may be used with or without the illustrated end effectors. For example, the containers described below may be utilized with any suitable conventional end effector, as well as the end effectors described below.

Within the shipping containers, a 450 mm diameter silicon wafer may experience 1-2 mm of gravitational sag deflection under static condition but a “shock cord” of ten G's would result in 10 to 20 mm of deflection. Since the wafers are typically stacked at a pitch spacing of 8-15 mm, this deflection could result in water-to-wafer contact and damage. Additionally, natural frequency resonance of the undamaged wafer planes could readily occur in the 1-20 Hertz range experienced under shipping conditions. Large and destructive vibration amplitudes would accompany such resonance conditions.

To mitigate these effects, the present invention utilizes a method of supporting/retaining the wafer whereby controlled deflection of the wafer is achieved. This deflection transforms the nominally flat wafer shape into a shape having a controlled curvature. This controlled curvature may be forced around a single bend axis or multiple bend axes. The beneficial consequence of the modified shape is that the rigidity of the substrate is markedly increased while the shape is retained in the deflected condition. As long as the surface stresses are kept below the material's yield or fracture point, the substrate will return to its original flat shape after the controlled deflection is removed. Effectively, the flat wafer plane is transformed into a beam structure whose rigidity may be one or more orders of magnitude greater than the wafer when left sagging in a conventional container. It should be appreciated that the controlled curvature may also be referred to as a bend or deflection around an axis.

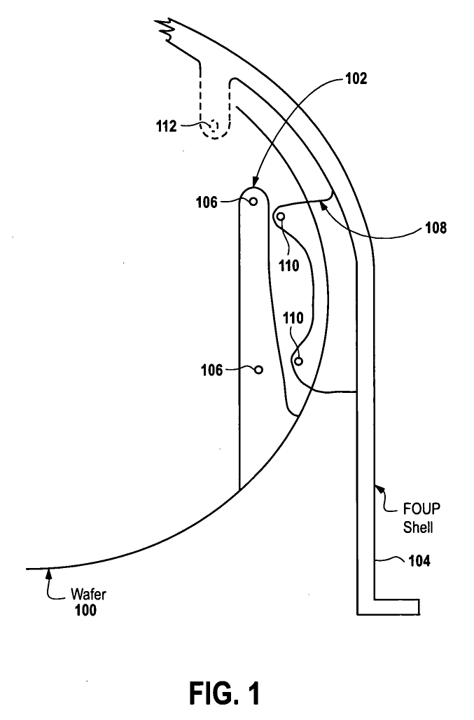

FIG. 1 is a simplified schematic diagram illustrating an end effector that may be utilized to transfer a substrate into a storage container in accordance with one embodiment of the invention. Front opening unified pod (FOUP) shell 104 houses a plurality of wafers 100. End effector 102 reaches into FOUP to place or remove wafer 100. End effector 102 is spread across a large diameter of wafer 100 due to the configuration of the support structure 108 of the FOUP. Support structure 108 includes support points 110 which support a bottom surface of wafer 100 proximate to a peripheral edge of wafer 100. Optionally support point 112 may be provided for FOUP shell 104. In an alternative end effector 102 may be included with a break-the-beam sensor that can be positioned above or below the corresponding support structure 108 when the end effector reaches into the FOUP. In yet another alternative embodiment, a reflective sensor may be integrated into the end effector. It should be appreciated that the container described herein may be employed with numerous end effector configurations. Further details on the end effectors can be found in U.S. application Ser. Nos.: 12/244693 and 12/253212, both of which are incorporated herein by reference for all purposes.

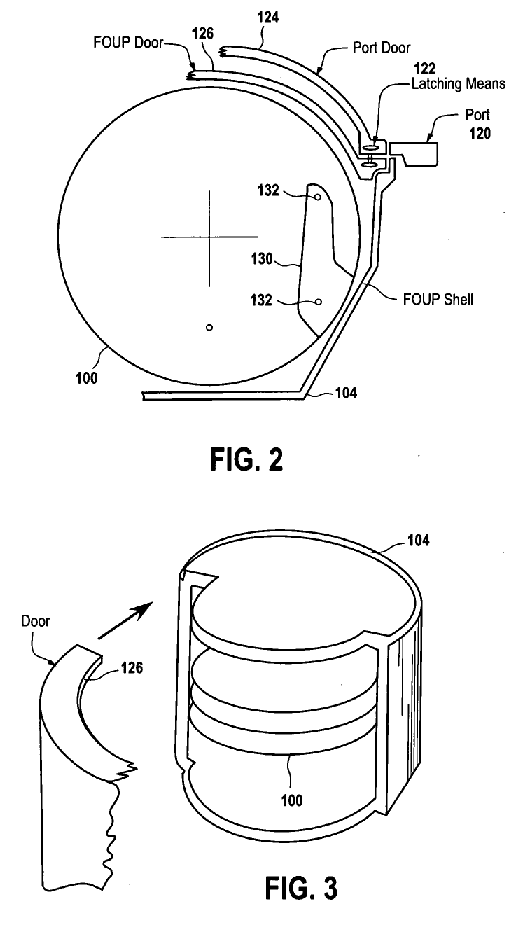

FIG. 2 is a simplified schematic diagram illustrating a configuration for a FOUP in accordance with one embodiment of the invention. It should be appreciated as substrates may increase from 300 millimeters to 450 millimeters the support structure for the FOUP will correspondingly increase. The embodiment of FIG. 2 provides for an alternative FOUP shell where the break point for manufacturing of the FOUP shell is moved back or cut away, relative to the embodiment of FIG. 1, in order to enable more efficient manufacturing of the FOUP. The FOUP includes shell 104 which mates with FOUP door 126. Port door 124 is latched to FOUP door 126 through a latching means 122. It should be appreciated that latching means 122 may be a keyed latching means in one embodiment. Port 120 is also provided. Support arm 130 provides support for a substrate within the FOUP. Support arm 130 has support points 132 located thereon. One skilled in the art will appreciate that the support arms may be configures as coplanar pairs as discussed in U.S. application Ser. No. 11/483366, which is incorporated herein by reference for all purposes. Wafer 100 will rest on support points 132 in one embodiment. It should be appreciated that any support structure may be used whether cantilevered or not with the FOUP illustrated in FIG. 2. As explained below, the support structure may include edge support constraints disposed on an inner surface of the FOUP shell and/or the FOUP door may be used to deflect or bend the substrate for rigid support during transportation. Thus, the support arms are optional for the transport container, as the bending of the substrate may move the surface of the substrate away from support points 132 of support arm 130.

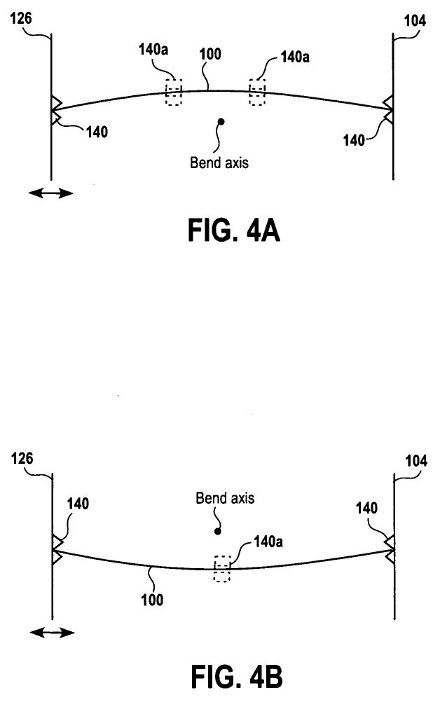

FIG. 3 is a simplified schematic diagram illustrating a perspective view of an FOUP in accordance of one embodiment of the invention. As illustrated in FIG. 3, the FOUP has an alternative configuration compared to FIG. 1 in order to assist in the manufacturing of the FOUP. Shell 104 may be molded during a manufacturing process and door 126 mates with shell 104 as described above with reference to FIG. 2. It should be appreciated that when door 126 is removed from shell 104 wafers 100 will project outside of the structure shell remaining.

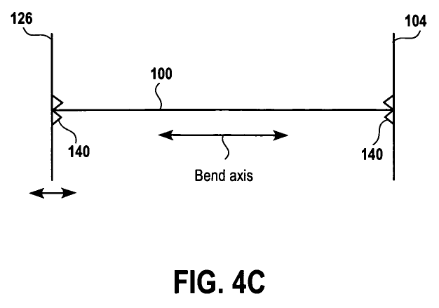

FIGS. 4A and 4C illustrate various container support mechanisms for use when shipping substrates and transporting substrates in accordance with one embodiment of the invention. Within FIGS. 4A, 4B and 4C, substrate 100 is held in a slightly bowed or deformed or deflected configuration in order to better accommodate any shock or vibration experienced during shipping. In FIGS. 4A and 4B the bend axis is defined on a line protruding out of the paper. In FIG. 4C the bend axis is defined on a line running from the door 126 to the back edge of shell 104. In one embodiment, the FOUP or shipping container includes a shell 104 against which a substrate 100 is placed. Door 126 is then moved into place and engages substrate 100 through V-groove 140, which functions as an edge support constraint. As door 126 is locked into place the deflection of substrate 100 is provided to rigidly hold substrate 100 between corresponding V-grooves 140, i.e., through touching a a radius of the edge of the substrate. In one embodiment, the shipping container includes sidewalls which may provide for V-grooves extending therefrom into an inner region of the FOUP in order to hold side areas of substrate 100 in place. In one embodiment, the wafer may sag when placed in the shipping container and the door may be engaged to controllably deflect the wafer while the side edges are held or supported, as illustrated in FIG. 4C.

It should be appreciated that numerous configurations are possible with the deflection of substrate 100 depending on the placement of V-grooves 140 and the mechanism used to push door 126 in. The deflection can take place in order to provide for a concave, convex, or any other deformation which rigidly holds substrate 100 in order to accommodate shock and vibration during any shipping, transporting, etc. One skilled in the art will appreciate that the bend axis may be between the front and back of the shipping container, i.e., between door 126 and a back side opposing door 126, as in FIG. 4C. Alternatively, the bend axis may be from a side to side of the shipping container, as illustrated in FIGS. 4A and 4B, i.e., along an axis that extends between door 126 and back edge of shell 104 without intersecting the back edge or the door. Furthermore, numerous bend axes may be provided depending on the deflection and force used to deflect wafer 100. That is, the deformation or deflection may be complex and have multiple bend axes in one embodiment.

In another embodiment, as illustrated in FIGS. 4A and 4B, additional edge support constraints may be placed within the interior surface of the container. For example support constraints 140a may be placed within the interior surface of the container, wherein edge support constraints 140a are offset from V-grooves 140 by 90 degrees. In this embodiment, edge support constraints 140a function to limit the deflection of the substrate by providing a stop surface that provides further rigidity. Numerous amounts of edge support constraints and placements may be utilized by the embodiments described herein and FIGS. 4A-4C are exemplary and not meant to be limiting. Edge support constraints 140a may be configured as v-grooves but are not limited to v-grooves, as any protruding surface may function as a stop to provide further rigidity. One skilled in the art will appreciate that the deflection from the bend axis may be smaller than 1 millimeter in one embodiment. In this embodiment, the distance between opposing edge support constraints may be less than the diameter of the substrate by a slight amount, e.g., less than a millimeter, to encourage the deflection. The material used for the edge support constraints 140 and 140a may be any suitable material compatible with the substrates where the material will not shed particles.

It should be appreciated that the container described herein may cause the deflection when the door is closed and/or latched. In one embodiment, through a cam, which is engaged when latching the door closed, the edge support constraints on the door can move vertically and in towards the substrate to cause the deflection. Additional mechanical structures enabling the vertical and inward movement may be integrated with the embodiments described herein and have not been discussed in detail so as not to obscure the described embodiments of the invention.

It should be appreciated that many of the inventive concepts described above would be equally applicable to the use of non-semiconductor manufacturing applications as well as semiconductor related manufacturing applications. Exemplary uses of the inventive concepts may be integrated into solar cell manufacturing and related manufacturing technologies, such as; single crystal silicon, polycrystalline silicon, thin film, and organic processes, etc. In addition, the embodiments may be extended to substrates having a shape other than a circular shape, e.g., square, rectangular, and other geometric shapes may take advantage of the embodiments described herein.

Any of the operations described herein that form part of the invention are useful machine operations. The invention also relates to a device or an apparatus for performing these operations. The apparatus can be specially constructed for the required purpose. In particular, various general-purpose machines can be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

1. A substrate container for storing at least one substrate, comprising:
a housing assembly encompassing the at least one substrate, the housing assembly having
a container door for access into an inner region of the housing assembly;
a support structure defined along sidewalls of the housing assembly, the support structure having a plurality of edge support constraints protruding towards the inner region of the housing assembly, the plurality of edge support constraints supporting opposing edge regions of the at least one substrate so as to cause the at least one substrate to deflect around an axis.

2. The substrate container as recited in claim 1, wherein a portion of the plurality of edge support constraints are attached to an inner surface of the container door.

3. The substrate container as recited in claim 1, wherein the container door is removable from the housing assembly.

4. The substrate container as recited in claim 1, wherein the housing assembly includes a plurality of support arms extending into the inner region of the housing assembly, the plurality of support arms arranged as horizontally coplanar pairs, wherein support arms of different horizontal planes are vertically aligned.

5. The substrate container as recited in claim 4, wherein the support arms extend further into the inner region than the edge support constraints.

6. The substrate container of claim 1, wherein the at least one substrate is a processed silicon wafer having a diameter of about 450 millimeters.

7. The substrate container of claim 1, wherein the edge support constraints are shaped as V-grooves and composed of a compliant material.

8. A substrate container for storing at least one substrate, comprising:
a housing enclosure;
a support structure having a plurality of vertically aligned edge support constraints, wherein spaced apart pairs of the plurality of the vertically aligned edge support constraints support a substrate in a substantially horizontal orientation, the spaced apart pairs being spaced apart at a distance less than a diameter than the substrate to cause the substrate to bend around an axis when stored therein.

9. The substrate container of claim 8, wherein a portion of the plurality of edge support constraints are attached to an inner surface of the container door.

10. The substrate container as recited in claim 8, wherein the container door is removable from the housing assembly.

11. The substrate container as recited in claim 8, wherein the housing assembly includes a plurality of support arms extending into the inner region of the housing assembly, the plurality of support arms arranged as horizontally coplanar pairs, wherein support arms of different horizontal planes are vertically aligned.

12. The substrate container of claim 8, wherein the substrate is a processed silicon wafer having a diameter of about 450 millimeters.

13. The substrate container of claim 8, wherein the edge support constraints are shaped as V-grooves and composed of a compliant material.

14. The substrate container of claim 8, wherein the container door being placed in a closed position causes the substrate to bend around the axis.

15. A method for supporting a semiconductor substrate within a container, comprising:
delivering the semiconductor substrate to the container; and
closing a door to the container to cause the semiconductor substrate to bend around an axis, the closing including latching the door for transportation of the container.

16. The method of claim 15, wherein the delivering is performed through an end effector.

17. The method of claim 15 wherein the semiconductor substrate has a diameter of about 450 millimeters.

18. The method of claim 15, wherein the closing forces the semiconductor substrate between opposing v-grooved extensions disposed on inner surfaces of the container.
